(19) United States
(12) Patent Application Publication
(10) Pub. No.: US 2009/0151781 A1
(43) Pub. Date: Jun. 18, 2009

(54) Solar cell having spherical surface and method of manufacturing the same

(75) Inventors: Ro Woon Lee, Seoul (KR); Jae Woo Joung, Gyeonggi-do (KR); Hye Jin Cho, Seoul (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/073,078

(22) Filed: Feb. 29, 2008

(30) Foreign Application Priority Data
Dec. 17, 2007 (KR) 10-2007-0132488

(51) Int. Cl. H01L 31/00; C23C 16/44

(52) U.S. Cl. 136/255; 427/255.6

(57) ABSTRACT

Provided is a solar cell having a spherical surface. The solar cell includes a substrate having a back contact layer formed thereon; a plurality of carbon nanoelectrodes formed on the back contact layer so as to cross the back contact layer at right angles; a p-type junction layer formed to have a plurality of spheres which surround the plurality of carbon nanoelectrodes; an n-type junction layer and a transparent electrode layer that are sequentially laminated on the p-type junction layer; a first electrode formed on one side of the top surface of the back contact layer; and a second electrode formed on one side of the top surface of the transparent layer.

### CROSS-REFERENCE TO RELATED APPLICATIONS

This application claims the benefit of Korean Patent Application No. 10-2007-0132488 filed with the Korea Intellectual Property Office on Dec. 17, 2006, the disclosure of which is incorporated herein by reference.

### BACKGROUND OF THE INVENTION

1. Field of the Invention

The present invention relates to a solar cell having a spherical surface and a method of manufacturing the same.

2. Description of the Related Art

In general, a solar cell has a pn junction layer formed in a semiconductor substrate and electrodes disposed in the upper and lower portions thereof. Such a solar cell has the following power-generation principle. When light with proper energy is incident on a single-crystal or non-crystal silicon semiconductor layer, electrons and holes are generated by an interaction between the incident light and the semiconductor layer. When an electric field caused by PN junction in the semiconductor layer is present, the electrons and the holes are diffused into the n-type semiconductor layer and the p-type semiconductor layer, respectively. At this time, as both electrodes are connected, the solar cell can generate electric power.

Conventionally, solar cells having such a power-generation principle have been manufactured as small-sized batteries so as to be applied as power supplies of small-sized electronic products. Recently, with the rapid development of the electronic and semiconductor technology, researches are being actively conducted in order to enhance characteristics of solar cells and to achieve cost reduction.

Hereinafter, a conventional method of manufacturing a solar cell will be described with reference to FIGS. 1 to 4.

FIGS. 1 to 4 are process diagrams showing a conventional method of manufacturing a solar cell.

First, as shown in FIG. 1, a substrate 110 is prepared. Then, a transparent conductive material is deposited on the prepared substrate 110 so as to form a back contact layer 120.

After the back contact layer 120 is formed, an n-type junction layer 130 is deposited on the back contact layer 120, as shown in FIG. 2. At this time, the n-type junction layer 130 is formed in such a manner that a portion of the top surface of the back contact layer 120 is exposed to the outside.

Then, as shown in FIG. 3, as a p-type junction layer 140 is deposited on the n-type junction layer 130, the PN junction layer 130 and 140 is completely formed.

After the pn junction layer 130 and 140 is formed, a first electrode 150 is formed on the exposed top surface of the back contact layer 120, and a second electrode 160 is formed on one side of the top surface of the p-type junction layer 140, as shown in FIG. 4.

The solar cell formed in such a manner is mounted with the substrate 110 positioned upward. Incident sunlight passes through the transparent electrode 120 so as to be absorbed by the n-type junction layer and the p-type junction layer 140 such that excited electrons are flown by an electromotive force. At this time, electric power is generated through the first and second electrodes 150 and 160.

However, the conventional solar cell manufactured by the above-described method has the following problems.

In the conventional solar cell, since the n-type junction layer 130 and the p-type junction layer 140 are formed in a plate shape, the surface area thereof is limited. Therefore, there is a limit in increasing light efficiency.

Further, incident sunlight is reflected or diffused by the substrate 110 such that some of the sunlight reaching the n-type junction layer 130 and the p-type junction layer 140 is lost. Therefore, the light efficiency is degraded.

### SUMMARY OF THE INVENTION

An advantage of the present invention is that it provides a solar cell having a spherical surface and a method of manufacturing the same, in which a p-type junction layer and an n-type junction layer having a plurality of spheres are formed on a plurality carbon nanoelectrodes through an inkjet printing process such that the surface area thereof is increased and sunlight can be concentrated. Therefore, it is possible to increase light efficiency.

Additional aspects and advantages of the present general inventive concept will be set forth in part in the description which follows and, in part, will be obvious from the description, or may be learned by practice of the general inventive concept.

According to an aspect of the invention, a solar cell having a spherical surface comprises a substrate having a back contact layer formed thereon; a plurality of carbon nanoelectrodes formed on the back contact layer so as to cross the back contact layer at right angles; a p-type junction layer formed to have a plurality of spheres which surround the plurality of carbon nanoelectrodes; an n-type junction layer and a transparent electrode layer that are sequentially laminated on the p-type junction layer; a first electrode formed on one side of the top surface of the back contact layer; and a second electrode formed on one side of the top surface of the transparent layer.

Preferably, the substrate is formed of any one selected from a copper foil, an aluminum foil, a glass wafer, and a silicon wafer, and the height of the carbon nanoelectrodes ranges from 3 to 4 μm.

Preferably, the spheres of the p-type junction layer have a diameter of 13 to 14 μm, and the spheres including the n-type junction layer and the transparent electrode layer have a diameter of 15 to 16 μm.

Preferably, the transparent electrode layer is formed of any one selected from ITO (Indium Tin Oxide), ZnO, and MgF₂.

According to another aspect of the invention, a method of manufacturing a solar cell having a spherical surface comprises the steps of: forming a back contact layer on a substrate; forming a plurality of transition metals on the back contact layer; growing the plurality of transition metals into a plurality of carbon nanoelectrodes which are perpendicular to the back contact layer; performing an inkjet printing process on the plurality of carbon nanoelectrodes so as to form a p-type junction layer having a plurality of spheres which surround the carbon nanoelectrodes; sequentially forming an n-type junction layer and a transparent electrode layer on the p-type junction layer; forming a first electrode on one side of the top surface of the back contact layer; and forming a second electrode on one side of the top surface of the transparent electrode layer.

Preferably, the substrate is formed of any one selected from a copper foil, an aluminum foil, a glass wafer, and a silicon wafer, and the transition metals are formed of Fe or Ni. Further, the transition metals are formed by performing an electron-beam evaporation process.

Further, the carbon nanoelectrodes are grown by performing a PECVD (Plasma Enhanced Chemical Vapor Deposition) process, and the carbon nanoelectrodes are grown to have a height of 3 to 4 μm.

Preferably, the spheres of the p-type junction layer have a diameter of 13 to 14 μm, and the n-type junction layer and the transparent electrode layer are formed by an inkjet printing process. Further, the spheres including the n-type junction layer and the transparent electrode layer have a diameter of 15 to 16 μm.

Preferably, the transparent electrode layer is formed of any one selected from ITO, ZnO, and MgF₂.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIGS. 1 to 4 are process diagrams showing a conventional method of manufacturing a solar cell;

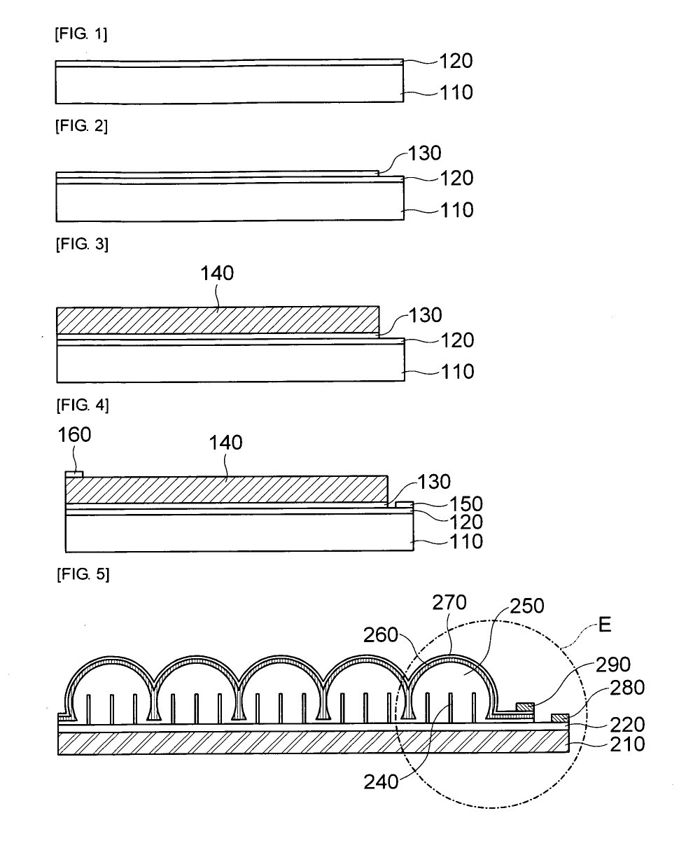

FIG. 5 is a cross-sectional view of a solar cell having a spherical surface according to the invention;

FIG. 6 is an expanded view of a portion E of FIG. 5; and

FIGS. 7 to 13 are process diagrams showing a method of manufacturing a solar cell having a spherical surface according to the invention.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, a solar cell having a spherical surface and a method of manufacturing the same according to an embodiment of the present invention will be described in detail with reference to the accompanying drawings.

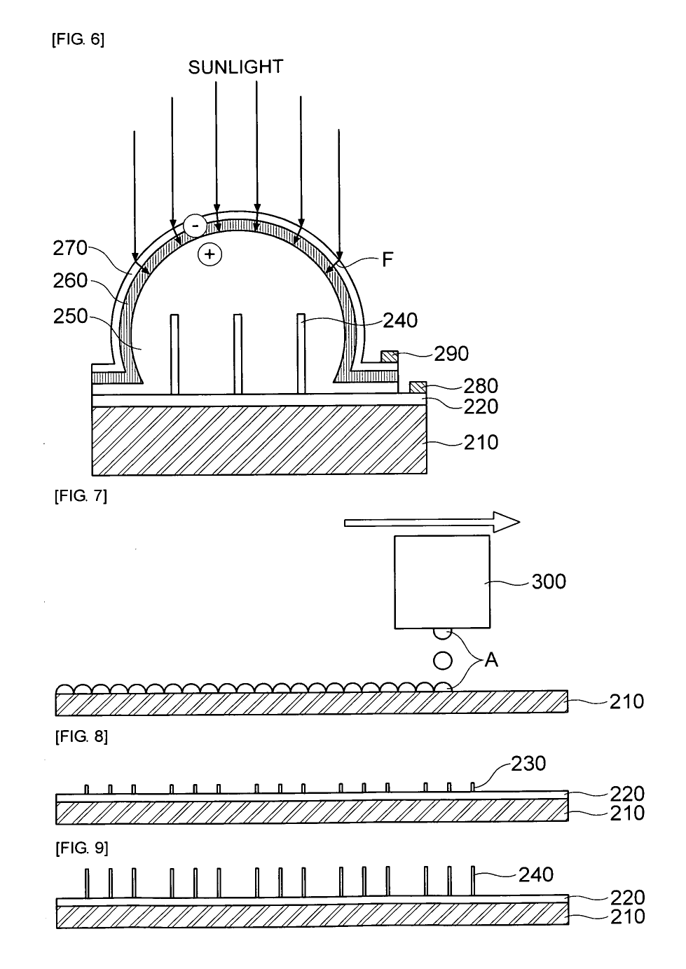

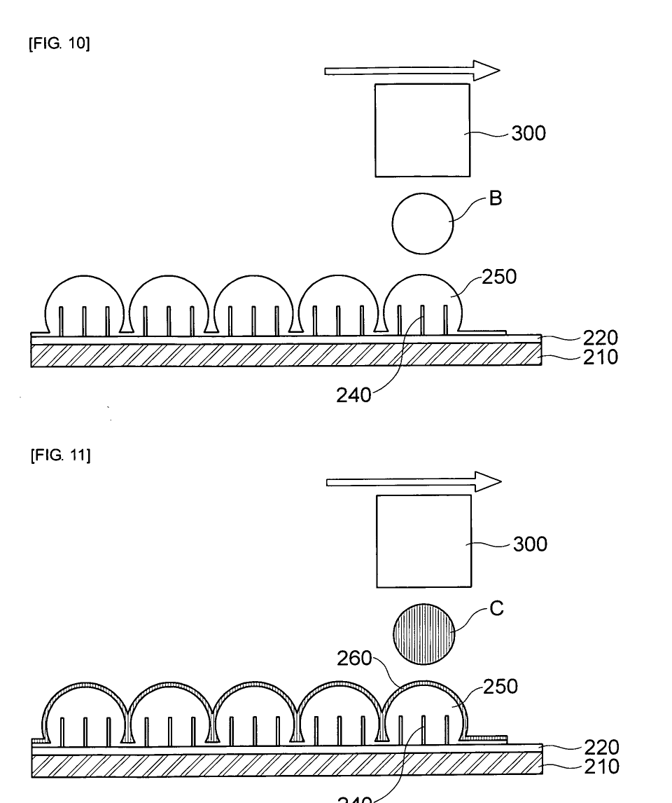

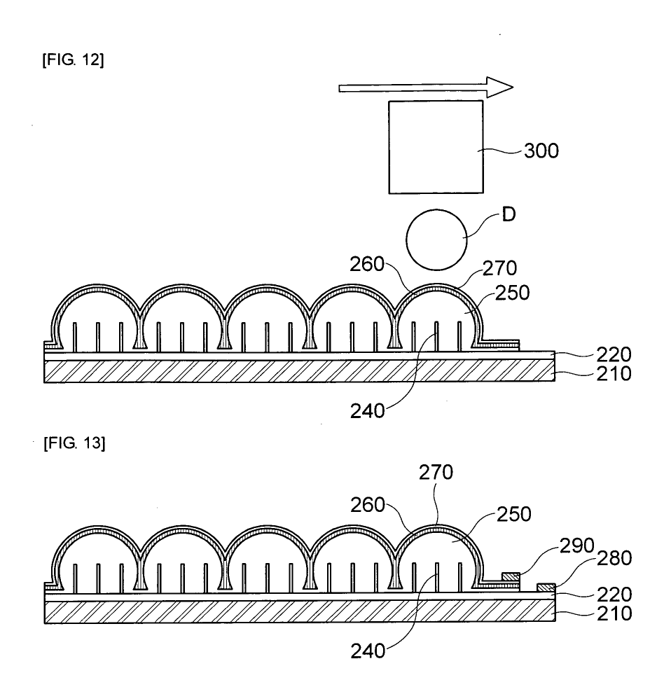

FIG. 5 is a cross-sectional view of a solar cell having a spherical surface according to the invention. FIG. 6 is an expanded view of a portion E of FIG. 5. FIGS. 7 to 13 are process diagrams showing a method of manufacturing a solar cell having a spherical surface according to the invention.

As shown in FIG. 5, the solar cell having a spherical surface according to the invention includes a back contact layer 220 formed on a substrate 210, a p-type junction layer 250, an n-type junction layer 260, and a transparent electrode layer 270, which are sequentially laminated on the back contact layer 220.

The solar cell has a plurality of carbon nanoelectrodes 240 formed in the p-type junction layer 250. The carbon nanoelectrodes 240 are formed vertically with respect to the top surface of the back contact layer 220.

Preferably, the substrate 210 is formed of any one selected from a glass wafer, a copper foil, an aluminum foil, and a silicon wafer.

Preferably, the p-type junction layer 250 is formed to have a plurality of spheres with a diameter of 13 to 14 μm. The reason is as follows. When the diameter of the spheres is set to less than 13 μm, the surface area thereof is reduced, so that there is a limit in enhancing light efficiency. Further, when the diameter of the spheres is set to more than 14 μm, the size of the solar cell increases, which makes it difficult to satisfy demand for reduction in size.

Preferably, the carbon nanoelectrodes 240 are formed to have a height of 3 to 4 μm. The reason is as follows. When the height of the carbon nanoelectrodes 240 is set to less than 3 μm, a distance from the surface of the p-type junction layer 250 increases, thereby degrading light efficiency. When the height of the carbon nanoelectrodes 240 is set to more than 4 μm, the carbon nanoelectrodes 240 may project from the surface of the p-type junction layer 250.

Preferably, the spheres including the n-type junction layer 260 and the transparent electrode layer 270 are formed to have a diameter of 15 to 16 μm. Further, the transparent electrode layer 270 is formed of any one selected from ITO (Indium Tin Oxide), ZnO, and MGF₂, which are transparent conductive materials.

In the solar cell having a spherical surface constructed in such a manner, the p-type junction layer 250, the n-type junction layer 260, and the transparent electrode layer 270 are formed in a spherical shape, and the carbon nanoelectrodes 240 are formed vertically with respect to the back contact layer 220, as shown in FIG. 6.

Accordingly, while sunlight incident from outside sequentially passes through the transparent electrode layer 270, the n-type junction layer 260, and the p-type junction layer 250, which have a spherical surface, the sunlight can be refracted to the inside so as to be concentrated, as indicated by an arrow F of FIG. 6. Therefore, the light efficiency of the solar cell can be enhanced, compared with the conventional solar cell having a flat surface.

Further, since the transparent electrode layer 270, the n-type junction layer 260, and the p-type junction layer 250 are formed in a spherical shape, the surface area of the solar cell can be increased. Since holes (+) which should reach the back contact layer 220 are delivered through the carbon nanoelectrodes 240 formed in the p-type junction layer 250, the light efficiency can be enhanced.

Hereinafter, a method of manufacturing a solar cell having a spherical surface according to the invention will be described in detail with reference to FIGS. 7 to 13.

First, as shown in FIG. 7, a substrate 210 is prepared. Preferably, the substrate 210 is formed of any one selected from a glass wafer, a copper foil, an aluminum foil, and a silicon wafer.

Then, a back contract layer 220 is formed on the prepared substrate 210. At this time, the back contact layer 220 is formed by an inkjet printing process for jetting droplets A with a predetermined diameter by using an inkjet printer 300.

After the back contact layer 220 is formed, a plurality of transition metals 230 are formed on the back contact layer 220. The plurality of transition metals 230 composed of Fe or Ni are formed to have a height of 3 to 10 nm. Preferably, the transition metals 230 are formed by an electron-beam evaporation process.

Then, the transition metals 230 are grown so as to form a plurality of carbon nanoelectrodes 240, as shown in FIG. 9. At this time, the plurality of carbon nanoelectrodes 240 are formed by performing a PECVD (Plasma Enhanced Chemical Vapor Deposition) process. Preferably, the carbon nanoelectrodes 240 are formed to have a height of 3 to 4 μm.

After the plurality of carbon nanoelectrodes 240 are formed, a p-type junction layer 250 having a plurality of spheres is formed to surround the plurality of carbon nanoelectrodes 240, as shown in FIG. 10. At this time, the p-type junction layer 250 is formed by the inkjet printing process. Preferably, the inkjet printing process is performed in such a manner that the spheres of the p-type junction layer 250 have a diameter of 13 to 14 μm. In order to adjust the diameter of droplets B, the size of an inkjet head of the inkjet printer 300, which is used in the inkjet printing process, can be adjusted.

Further, the p-type junction layer 250 is formed so as not to cover the entire top surface of the back contact layer 220. In other words, the p-type junction layer 250 is formed to expose one side of the top surface of the back contact layer 220, where a first electrode is to be formed.

Then, as shown in FIG. 11, the inkjet printing process is performed on the p-type junction layer 250 having a plurality of spheres, thereby forming an n-type junction layer 260. At this time, in the inkjet printing process, the size of droplets C is adjusted in such a manner that the spheres including the n-type junction layer 260 have a diameter of 15 to 16 μm.

After the n-type junction layer 260 is formed, a transparent electrode layer 270 is formed by performing the inkjet printing process on the n-type junction layer 260, as shown in FIG. 12. Preferably, the transparent electrode layer 270 is composed of a transparent conductive material which is selected from ITO, ZnO, and MgF₂.

After the transparent electrode layer 270 is formed, a first electrode is formed on the exposed top surface of the back contact layer 220, and a second electrode with a predetermined pattern is formed on one side of the top surface of the transparent electrode layer 270.

In the method of manufacturing a solar cell having a spherical surface according to the invention, the p-type junction layer 250, the n-type junction layer 260, and the transparent electrode layer 270 are formed in a spherical shape by the inkjet printing process such that the surface area of the solar cell can be increased. Further, incident sunlight can be concentrated, which makes it possible to enhance light efficiency.

Further, while the conventional solar cell is manufactured by the photolithography process, the solar cell according to the invention is manufactured by the inkjet printing process which is simpler than the photolithography process. Therefore, it is possible to reduce the manufacturing process.

According to the invention, as the p-type junction layer and the n-type junction layer having the plurality of spheres are formed on the carbon nanoelectrodes through the inkjet printing process, the surface area can be increased, and the sunlight can be concentrated. Therefore, it is possible to enhance light efficiency.

Further, since the p-type junction layer, the n-type junction layer, and the transparent electrode layer are formed through the inkjet printing process, the time required for the manufacturing process can be reduced, and the manufacturing process can be simplified.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A solar cell having a spherical surface comprising:
a substrate having a back contact layer formed thereon;
a plurality of carbon nanoelectrodes formed on the back contact layer so as to cross the back contact layer at right angles;
a p-type junction layer formed to have a plurality of spheres which surround the plurality of carbon nanoelectrodes;
an n-type junction layer and a transparent electrode layer that are sequentially laminated on the p-type junction layer;
a first electrode formed on one side of the top surface of the back contact layer; and
a second electrode formed on one side of the top surface of the transparent layer.

2. The solar cell according to claim 1, wherein the substrate is formed of any one selected from a copper foil, an aluminum foil, a glass wafer, and a silicon wafer.

3. The solar cell according to claim 1, wherein the height of the carbon nanoelectrodes ranges from 3 to 4 μm.

4. The solar cell according to claim 1, wherein the spheres of the p-type junction layer have a diameter of 13 to 14 μm.

5. The solar cell according to claim 1, wherein the spheres including the n-type junction layer and the transparent electrode layer have a diameter of 15 to 16 μm.

6. The solar cell according to claim 1, wherein the transparent electrode layer is formed of any one selected from ITO (Indium Tin Oxide), ZnO, and MgF₂.

7. A method of manufacturing a solar cell having a spherical surface, comprising the steps of:
forming a back contact layer on a substrate;
forming a plurality of transition metals on the back contact layer;
growing the plurality of transition metals into a plurality of carbon nanoelectrodes which are perpendicular to the back contact layer;
performing an inkjet printing process on the plurality of carbon nanoelectrodes so as to form a p-type junction layer having a plurality of spheres which surround the carbon nanoelectrodes;
sequentially forming an n-type junction layer and a transparent electrode layer on the p-type junction layer;
forming a first electrode on one side of the top surface of the back contact layer; and
forming a second electrode on one side of the top surface of the transparent electrode layer.

8. The method according to claim 7, wherein the substrate is formed of any one selected from a copper foil, an aluminum foil, a glass wafer, and a silicon wafer.

9. The method according to claim 7, wherein the transition metals are formed of Fe or Ni.

10. The method according to claim 7, wherein the transition metals are formed by performing an electron-beam evaporation process.

11. The method according to claim 7, wherein the carbon nanoelectrodes are grown by performing a PECVD (Plasma Enhanced Chemical Vapor Deposition) process.

12. The method according to claim 7, wherein the carbon nanoelectrodes are grown to have a height of 3 to 4 μm.

13. The method according to claim 7, wherein the spheres of the p-type junction layer have a diameter of 13 to 14 μm.

14. The method according to claim 7, wherein the n-type junction layer and the transparent electrode layer are formed by an inkjet printing process.

15. The method according to claim 7, wherein the spheres including the n-type junction layer and the transparent electrode layer have a diameter of 15 to 16 μm.

16. The method according to claim 7, wherein the transparent electrode layer is formed of any one selected from ITO, ZnO, and MgF₂.
